(19) United States
(12) Patent Application Publication
(10) Pub. No.: US 2024/0184221 A1
(43) Pub. Date: Jun. 6, 2024

(54) ALIGNMENT METHOD AND ASSOCIATED ALIGNMENT AND LITHOGRAPHIC APPARATUSES

(71) Applicant: ASML NETHERLANDS B.V., Veldhoven (NL)

(72) Inventors: Samee Ur REHMAN, Milpitas, CA (US); Boris MENCHTCHIKOV, Redwood City, CA (US); Robert John SOCHA, Campbell, CA (US)

(73) Assignee: ASML NETHERLANDS B.V., Veldhoven (NL)

(21) Appl. No.: 18/279,121

(22) PCT Filed: Feb. 18, 2022
(86) PCT No.: PCT/EP2022/054161

§ 371 Date: Aug. 28, 2023

Related U.S. Application Data
(60) Provisional application No. 63/159,042, filed on Mar. 10, 2021.

(51) Int. Cl. G03F 9/00

(52) U.S. Cl. CPC G03F 9/7042; G03F 9/7019; G03F 9/7088

(57) ABSTRACT

A method of identifying one or more dominant asymmetry modes relating to asymmetry in an alignment mark, the method includes obtaining alignment data relating to measurement of alignment marks on at least one substrate using a plurality of alignment conditions; identifying one or more dominant orthogonal components of the alignment data, the one or more dominant orthogonal components including a number of orthogonal components which together sufficiently describes variance in the alignment data; and determining an asymmetry mode as dominant if it corresponds to an expected asymmetry mode shape which best matches one of the one or more dominant orthogonal components. Alternatively, the method includes, for each known asymmetric mode: determining a sensitivity metric; and determining an asymmetry mode as dominant if the sensitivity metric is above a sensitivity threshold.

### CROSS-REFERENCE TO RELATED APPLICATIONS

This application claims priority of U.S. application 63/159,042 which was filed on 10 Mar. 2021, and which is incorporated herein in its entirety by reference.

### FILED OF INVENTION

The present invention relates to methods and apparatus usable, for example, in the manufacture of devices by lithographic techniques, and to methods of manufacturing devices using lithographic techniques. The invention relates to metrology devices, and more specifically metrology devices used for measuring position such as alignment sensors and lithography apparatuses having such an alignment sensor.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor or alignment sensor (both terms are used synonymously), typically an optical position sensor.

The lithographic apparatus includes one or more alignment sensors by which positions of marks on a substrate can be measured accurately. Different types of marks and different types of alignment sensors are known from different manufacturers and different products of the same manufacturer. A type of sensor widely used in current lithographic apparatus is based on a self-referencing interferometer as described in U.S. Pat. No. 6,961,116 (den Boef et al). Various enhancements and modifications of the position sensor have been developed, for example as disclosed in US2015261097A1. The contents of all of these publications are incorporated herein by reference.

Imperfections in alignment marks can result in a wavelength/polarization dependent variation in a measured value from that mark. As such, correction and/or mitigation for this variation is sometimes effected by performing the same measurement using multiple different wavelengths and/or polarizations (or more generally, multiple different illumination conditions). It would be desirable to improve one or more aspects of measuring using multiple illumination conditions.

### SUMMARY OF THE INVENTION

The invention in a first aspect provides a method of identifying one or more dominant asymmetry modes relating to asymmetry in an alignment mark, the method comprising either: steps A): obtaining alignment data relating to measurement of alignment marks on at least one substrate using a plurality of alignment conditions; identifying one or more dominant orthogonal components of said alignment data, said one or more orthogonal components comprising a number of said orthogonal components which together sufficiently describes variance in said alignment data; and determining an asymmetry mode as dominant if it corresponds to an expected asymmetry mode shape which best matches one of said dominant orthogonal components; or steps B): for each known asymmetric mode: determining a sensitivity metric; and determining an asymmetry mode as dominant if said sensitivity metric is above a sensitivity threshold.

Also disclosed is a computer program, alignment sensor and a lithographic apparatus being operable to perform the method of the first aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 is a schematic illustration of an alignment sensor adaptable according to an embodiment of the invention; and

FIG. 4 is a flowchart of a method for determining dominant asymmetry modes in accordance with a first embodiment of the invention; and

FIG. 5 is a flowchart of a method for determining dominant asymmetry modes in accordance with a second embodiment of the invention.

### DETAILED DESCRIPTION OF EMBODIMENTS

Before describing embodiments of the invention in detail, it is instructive to present an example environment in which embodiments of the present invention may be implemented.

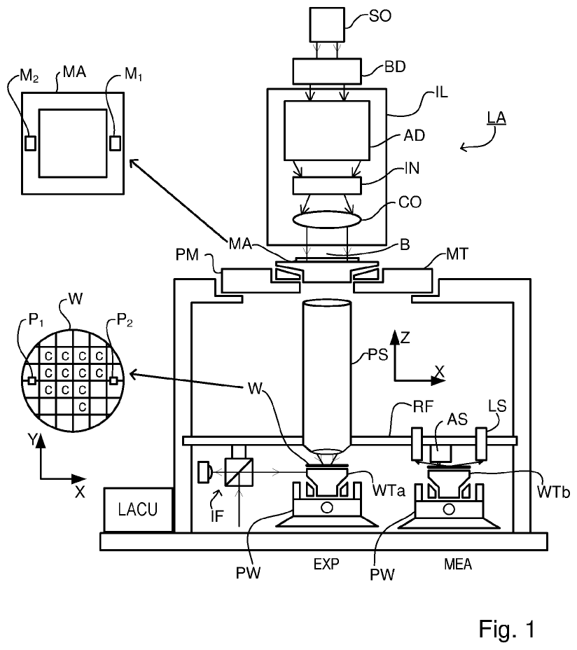

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA —between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

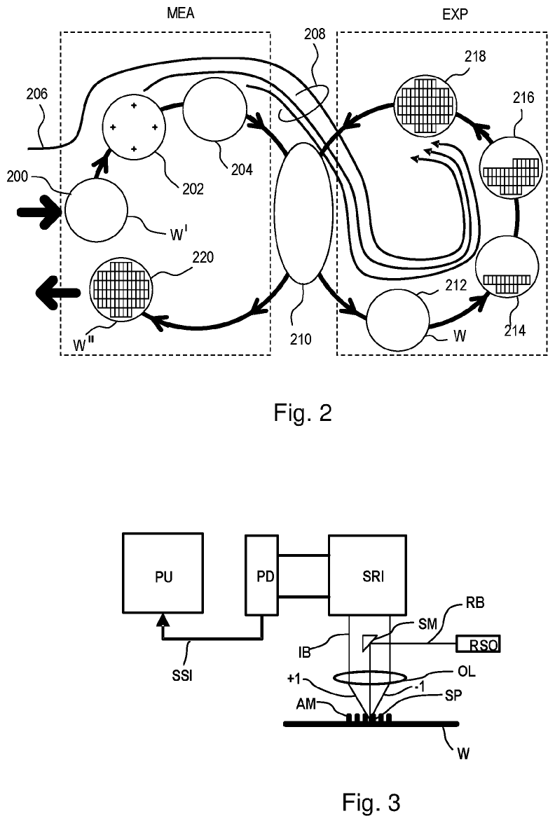

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers (by the same apparatus or a different lithographic apparatus). For this purpose, the substrate is provided with one or more sets of marks. Each mark is a structure whose position can be measured at a later time using a position sensor, typically an optical position sensor. The position sensor may be referred to as “alignment sensor” and marks may be referred to as “alignment marks”.

A lithographic apparatus may include one or more (e.g. a plurality of) alignment sensors by which positions of alignment marks provided on a substrate can be measured accurately. Alignment (or position) sensors may use optical phenomena such as diffraction and interference to obtain position information from alignment marks formed on the substrate. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

A mark, or alignment mark, may comprise a series of bars formed on or in a layer provided on the substrate or formed (directly) in the substrate. The bars may be regularly spaced and act as grating lines so that the mark can be regarded as a diffraction grating with a well-known spatial period (pitch). Depending on the orientation of these grating lines, a mark may be designed to allow measurement of a position along the X axis, or along the Y axis (which is oriented substantially perpendicular to the X axis). A mark comprising bars that are arranged at +45 degrees and/or −45 degrees with respect to both the X- and Y-axes allows for a combined X- and Y-measurement using techniques as described in US2009/195768A, which is incorporated by reference.

The alignment sensor scans each mark optically with a spot of radiation to obtain a periodically varying signal, such as a sine wave. The phase of this signal is analyzed, to determine the position of the mark and, hence, of the substrate relative to the alignment sensor, which, in turn, is fixated relative to a reference frame of a lithographic apparatus. So-called coarse and fine marks may be provided, related to different (coarse and fine) mark dimensions, so that the alignment sensor can distinguish between different cycles of the periodic signal, as well as the exact position (phase) within a cycle. Marks of different pitches may also be used for this purpose.

Measuring the position of the marks may also provide information on a deformation of the substrate on which the marks are provided, for example in the form of a wafer grid. Deformation of the substrate may occur by, for example, electrostatic clamping of the substrate to the substrate table and/or heating of the substrate when the substrate is exposed to radiation.

FIG. 3 is a schematic block diagram of an embodiment of a known alignment sensor AS. Radiation source RSO provides a beam RB of radiation of one or more wavelengths, which is diverted by diverting optics onto a mark, such as mark AM located on substrate W, as an illumination spot SP. In this example the diverting optics comprises a spot mirror SM and an objective lens OL. The illumination spot SP, by which the mark AM is illuminated, may be slightly smaller in diameter than the width of the mark itself.

Radiation diffracted by the mark AM is collimated (in this example via the objective lens OL) into an information-carrying beam RB. The term “diffracted” is intended to include complementary higher diffracted orders; e.g., +1 and −1 diffracted orders (labelled +1, −1) and optionally zero-order diffraction from the mark (which may be referred to as reflection). A self-referencing interferometer SRI, e.g. of the type disclosed in 056961116 mentioned above, interferes the beam TB with itself after which the beam is received by a photodetector PD. Additional optics (not shown) may be included to provide separate beams in case more than one wavelength is created by the radiation source RSO. The photodetector may be a single element, or it may comprise a number of pixels, if desired. The photodetector may comprise a sensor array.

The diverting optics, which in this example comprises the spot mirror SM, may also serve to block zero order radiation reflected from the mark, so that the information-carrying beam IB comprises only higher order diffracted radiation from the mark AM (this is not essential to the measurement, but improves signal to noise ratios).

SRI Intensity signals SSI are supplied to a processing unit PU. By a combination of optical processing in the self-referencing interferometer SRI and computational processing in the unit PU, values for X- and Y-position on the substrate relative to a reference frame are output.

A single measurement of the type illustrated only fixes the position of the mark within a certain range corresponding to one pitch of the mark. Coarser measurement techniques are used in conjunction with this to identify which period of a sine wave is the one containing the marked position. The same process at coarser and/or finer levels are repeated at different wavelengths for increased accuracy and/or for robust detection of the mark irrespective of the materials from which the mark is made, and materials on and/or below which the mark is provided. Improvements in performing and processing such multiple wavelength measurements are disclosed below.

In the context of wafer alignment, the following approaches are in use or have been proposed to correct the mark position for mark asymmetry (asymmetry in the alignment mark which results in a position error or offset): OCW (Optimal Color Weighing—described in more detail in US publication US2019/0094721 A1 which is incorporated herein by reference), OCIW (Optimal Color and Intensity Weighing—described in more detail in PCT publication WO 2017032534 A2) and WAMM (Wafer Alignment Model Mapping—described in more detail in PCT publications WO 2019001871 A1 and WO 2017060054 A1).

The concept of OCW is to determine a weighting for each of the available colors or color/polarization combinations (or a subset of the available colors or illumination settings, where an illumination setting is a particular color/polarization combination) which improve the accuracy of an alignment measurement. In particular, processing effects on alignment marks result in undesired mark asymmetries. These mark asymmetries (and possibly other asymmetries in the sensor optics) result in an error contribution in the alignment signal (measured alignment position). This error contribution varies from color to color, when of course the actual alignment position is color independent. Because of this, real-world alignment measurements on imperfect marks show a measured position dependence on color or illumination setting.

The weighting may comprise a correction, for which a weight is determined per illumination setting. These weights can then be applied to an aligned position as determined respectively from each illumination setting.

In OCW as disclosed in US2019/0094721, a least squares optimization is performed on alignment model fit coefficients X, in terms of a set of weights w comprising a weight for each of the colors. These weights w̅ are considered optimal when they minimize the difference between alignment and overlay metrology y̅; i.e., the optimization finds the weights w which best satisfies:

Xw̅=y̅

Another method for determining weights for OCW may be referred to as stack-based OCW, where a Monte-Carlo search is performed over variation of a pre-defined set of asymmetry modes in order to learn the weights to be fed into the scanner. Stack-based OCW is described in more detail in Menchtchikov, Boris et al: “Reduction in overlay error from mark asymmetry using simulation, ORION, and alignment models”; Proceedings Volume 10587, Optical Microlithography XXXI; 105870C (2018). This document is hereby incorporated by reference.

Existing methods for such stack-based OCW methods do not have a systematic method for asymmetry mode selection. The state of the art approach for stack-based OCW requires a user to arbitrarily select the dominant asymmetry modes and, for each one, to match a simulated quality metric to the measured quality metric. The quality metric may be alignment wafer quality (WQ), where WQ is a measure of the strength of a signal from an alignment mark. As such, present methods require Wafer Quality matching. This means that the stack is modified such that the simulated wafer quality matches the measured wafer quality. Even with arbitrary asymmetry selection, this step is performed to provide a good match for the symmetric variations (thin film).

More specifically, stack-based OCW comprises a setup step where dominant asymmetry modes are arbitrarily chosen. Examples of asymmetry modes may include, for example, one or more top tilt modes, one or more bottom (floor) tilt modes (e.g., left floor and right floor of a single alignment mark feature or line), one or more side wall angle modes (e.g., left wall and right wall of a single alignment mark feature or line). A suitable alignment mark model within a simulation environment may be used, within which process variations per identified dominant asymmetry mode are varied randomly and assessed (i.e., a Monte Carlo method). The assessment may comprise determining (e.g., using the model and simulation environment) a swing curve per asymmetry mode. A swing curve may describe the variation of a sensitivity metric (e.g., sensitivity of measured aligned position to variation of the asymmetry mode) with wavelength or illumination condition. A weighting can then be calculated which maximizes alignment accuracy over a suitable range of process variations, for each of the swing curves. More specifically, the weights may be calculated such that alignment is least sensitive to the process variations (i.e., the weighting minimizes sensitivity to the process variation). This may be achieved by giving more weight to colors which are least impacted by the simulated Monte Carlo response of the process variations.

In this disclosure, two main improvements are proposed; firstly an automated method for identifying the dominant asymmetries in the stack and secondly (at least for some embodiments) using a reference library comprising wafer shapes of expected asymmetry modes based on prior knowledge of how their unique fingerprints vary spatially over the wafer.

Two embodiments will be described, a first embodiment where actual measurement data is available (measured on at least one wafer) and a second embodiment where only synthetic data is available as synthesized by the simulation application. In both embodiments, a suitable model and simulation environment may be used such as, for example, a software target/mark simulator called design for control (D4C) alignment. D4C alignment may be used to design wafer alignment marks with minimal sensitivity to process variations, while also having good detectability and measurement reproducibility. The basic concept of the D4C simulator is described in US patent application US20160140267A1, which is incorporated herein by reference.

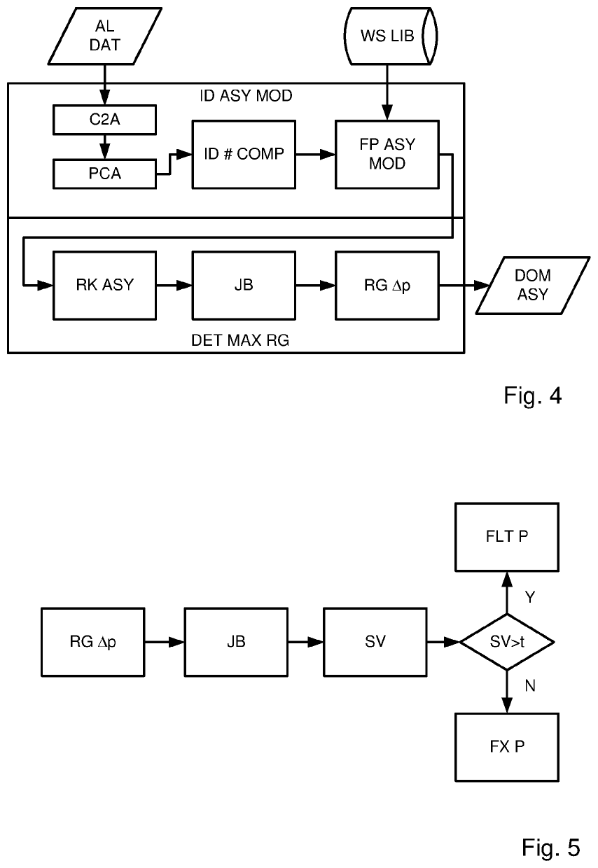

FIG. 4 is a flowchart describing a method for determining dominant asymmetries and their respective ranges according to the first embodiment. In a first stage, measured alignment data is used to identify dominant asymmetry modes ID ASY MOD. Alignment data AL DAT from at least one wafer and relating to a plurality of illumination conditions is obtained. A Color-to-average signal C2A is generated from the alignment data by subtracting the average alignment value over all illumination conditions from each alignment value relating to a respective one of said illumination conditions. A component analysis is then performed on the Color-to-average data to identify orthogonal components or orthogonal fingerprints within the Color-to-average data. Any suitable component analysis may be used, such as a Principal Component Analysis PCA, Independent Component Analysis ICA, Singular Value Decomposition (SVD). In this example, PCA is used and it may be expected that the principal components (e.g., each comprising a respective fingerprint; i.e., a spatial distribution over a wafer or portion thereof) each correspond with one or more asymmetry modes or process variations (note that more than one asymmetry mode may correspond to a single fingerprint).

Thereafter, the number of dominant principal components is determined ID #COMP, this corresponding to the number of asymmetry modes which are deemed dominant. This step may comprise determining the number of principal components which are required to explain a certain pre-defined percentage of variance (e.g., a variance threshold) in the Color-to-average data.

In the next step FP ASY MOD, the wafer fingerprint corresponding to each of the principal components is compared with a library of pre-defined wafer shapes of expected asymmetries WS LIB in order to map each fingerprint to a one or more root-cause asymmetry modes (e.g. to map a first principal component fingerprint to a first asymmetry mode (e.g., SWA) and a second principal component fingerprint to a second asymmetry mode (e.g., top tilt)). The library may comprise e.g., between 3 and 10, between 4 and 8, or between 4 and 7 wafer shapes, each of which comprise an alignment fingerprint (spatial distribution of alignment data) representative of a particular asymmetry mode. A suitable correlation or similarity metric may be used to identify the commonality between each principal component fingerprint and the pre-defined wafer shapes. Examples of suitable correlation or similarity metrics to perform the mapping include Pearson's correlation or a mutual information metric. It is assumed that the shape library is exhaustive in the sense that it encapsulates all possible asymmetric process variations. If it is found that the correlation between the principal component fingerprints and the shape library is low for all shapes, then this may be used as an indicator that the library is missing some important process variations. This, in turn, may be used as a trigger to update the shape library LIB.

In a second stage DET MAX RG, a suitable alignment mark model (e.g., D4C model) and measured alignment data AL DAT may be used to determine a maximum range Δp for each asymmetry mode. The identified dominant asymmetry modes are ranked RK ASY according to their relative importance; for example, according to principal component order such that the asymmetry(s) corresponding to the first principal component is/are ranked highest, the asymmetry(s) corresponding to the second principal component is/are ranked second and so on.

In the next step, the alignment mark model (e.g., D4C) may be used to compute a sensitivity metric or Jacobian JB (where the Jacobian is a sensitivity metric) for each dominant asymmetry mode. To calculate the Jacobian, the derivative of alignment position deviation with respect to each asymmetry mode may be determined for each illumination condition. Therefore, if for example, there are 12 wavelengths and 2 polarizations, this would result in 24 derivatives per asymmetry. The model may calculate the derivative using finite difference, i.e., the model can be used to compute alignment at a given illumination condition for different values of the asymmetry mode with the derivative being described by the slope.

The maximum range for each asymmetry RG Δp may be determined by solving of an inverse problem using the Jacobian for each dominant asymmetry mode and the principal component projected color-to-average alignment data for the component corresponding to that asymmetry mode. If each fingerprint corresponds to a single root-cause asymmetry mode, the maximum ranged Δpₖ for kth asymmetry mode or corresponding asymmetry parameter pₖ may be estimated as:

Δpₖ=arg max(Jₖ⁻¹·AL_{comp-k})

Where Jₖ is the Jacobian for the kth asymmetry mode and AL_{comp-k} is the color-to-average alignment data corresponding to principal component k (i.e., the principal component corresponding to the kth asymmetry mode). When multiple asymmetry modes correspond to a single fingerprint, this equation translates to having multiple columns of Jacobians, each column corresponding to a single asymmetry mode.

The dominant asymmetries DOM ASY and their associated ranges Δpₖ are then returned as the output.

The second embodiment for determining dominant asymmetries is based on there being only synthetic alignment data available (e.g., as output from the D4C/alignment mark model).

FIG. 5 is a flowchart describing such a method. The illustrated flow is performed for each known asymmetric mode and/or associated asymmetric parameter. In this embodiment, the ranges for each asymmetry mode are set or provided by a user RG Δp. The Jacobian JB is determined for each asymmetry mode using a suitable alignment mark model (e.g., a D4C model), e.g., according to the methods described in relation to the first embodiment. The sensitivity metric SV is then determined for each asymmetry mode k using the assigned maximum range Δp and the determined Jacobian; e.g., according to:

SV(pₖ)=|Δpₖ∥Jₖ∥

If the computed sensitivity SV (pₖ) is above a (e.g., predetermined) threshold t, then the asymmetry is considered dominant and the corresponding parameter(s) pₖ are floated for the model in the simulation to determine the OCW. On the other hand, if the sensitivity is below this threshold, then the asymmetry is considered to not be dominant and the corresponding parameter(s) pₖ fixed.

In either embodiment, the identified dominant asymmetries and their ranges can then be used as the input for determining OCW weights using Monte-Carlo simulation, as has been described. In such a simulation, the model parameters corresponding to the identified dominant asymmetry modes may be floated (variable parameters), and the model parameters corresponding to the asymmetry modes not identified as being dominant may be fixed.

This may comprise determining (e.g., using a D4C model or other suitable alignment mark modeling and simulation environment) a swing curve per determined dominant asymmetry mode. A stack simulation within the D4C environment may be performed to evaluate a sensitivity metric per dominant asymmetry (as a function of illumination condition) as a ratio of variation of aligned position (as a function of illumination condition) with variation of the respective asymmetry mode/parameter pₖ. By way of specific example, a first sensitivity s₁(λ) swing curve and a second sensitivity s₂ (λ) may be determined as:

$${s}_{1} ( λ ) = \frac{Δ A L ( λ )}{Δ {p}_{1}} , {s}_{2} ( λ ) = \frac{Δ AL ( λ )}{Δ {p}_{2}}$$

where ΔAL(λ) is the aligned position data and Δpₜ and Δp₂ may, for example, be ΔTT, ΔSWA or corresponding model parameters thereto; e.g., measure of asymmetry of a first asymmetry mode (e.g., top tilt) and second asymmetry mode (e.g., side wall angle) respectively.

A weighting can then be calculated which maximizes alignment accuracy and/or minimizes this sensitivity metric over the respective determined maximum range of process variations, for each of the swing curves (and therefore for each of the determined asymmetry modes).

It can be appreciated that the dominant asymmetry selection method does not require WQ matching, unlike the prior art arbitrary selection method. However, the dominant asymmetry selection method disclosed herein may still optionally include a WQ matching step, e.g., as this may help train more robust weights.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

Embodiments of the present disclosure can be further described by the following clauses.

1. A method of identifying one or more dominant asymmetry modes relating to asymmetry in an alignment mark, the method comprising either:
steps A): obtaining alignment data relating to measurement of alignment marks on at least one substrate using a plurality of alignment conditions; identifying one or more dominant orthogonal components of said alignment data, said one or more orthogonal components comprising a number of said orthogonal components which together sufficiently describes variance in said alignment data; and determining an asymmetry mode as dominant if it corresponds to an expected asymmetry mode shape which best matches one of said dominant orthogonal components; or
steps B): for each known asymmetric mode: determining a sensitivity metric; and determining an asymmetry mode as dominant if said sensitivity metric is above a sensitivity threshold.
   2. A method as in steps A) of clause 1, wherein the number of dominant orthogonal components comprises the minimum number which together sufficiently describes variance in said alignment data.
   3. A method as in clause 2, wherein determining the number of orthogonal components which together sufficiently describes variance in said alignment data comprises determining the number of orthogonal components required to explain a certain threshold percentage of variance.
   4. A method as in any clause 2 or 3, wherein said alignment data comprises color-to-average data comprising a difference of each alignment value relating to a respective one of said illumination conditions and an average alignment value over all illumination conditions.
   5. A method as in any of clauses 2 to 4, wherein the step of determining an asymmetry mode as dominant if it corresponds to an expected asymmetry mode shape which best matches one of said dominant orthogonal components comprises comparing each orthogonal component to a library of expected asymmetry mode shapes, each corresponding to at least one asymmetry mode.
   6. A method as in clause 5, wherein said comparing step uses a correlation or similarity metric to quantify the comparison.
   7. A method as in clause 6, wherein said correlation or similarity metric comprises Pearson's correlation or a mutual information metric.
   8. A method as in any of clauses 5 to 7, triggering an update for the library should no good match be found for a orthogonal component within said library.
   9. A method as in any of clauses 2 to 8, comprising determining a maximum variation range for asymmetry variation for each dominant asymmetric mode.
   10. A method as in clause 9, wherein determining a maximum variation range comprises obtaining an alignment mark model for modeling performance of an alignment mark;
using said alignment mark model to determine a sensitivity metric or Jacobian of each said asymmetry mode; and determining the maximum range from said sensitivity metric or Jacobian.
   11. A method as in clause 10, wherein said determining a maximum variation range comprises solving an inverse problem defined by the sensitivity metric or Jacobian for each dominant asymmetry mode and the orthogonal component corresponding to that asymmetry mode.
   12. A method as in any preceding clause, wherein each orthogonal component comprises a principal component obtained from a principal component analysis.
   13. A method as in steps B) of clause 1, further comprising:
obtaining an alignment mark model for modeling performance of an alignment mark; and;
using said alignment mark model to determine the sensitivity metric.
   14. A method as in clause 13, wherein said step of using said alignment mark model to determine the sensitivity metric comprises using said alignment mark model to determine the Jacobian of each said asymmetry mode.
   15. A method as in clause 14, wherein the sensitivity metric for each asymmetry mode is determined from the corresponding Jacobian and a variation range for asymmetry variation of the asymmetric mode.
   16. A method as in any preceding clause, comprising using said dominant asymmetry modes to determine a set of correction weights to correct alignment data.
   17. A method as in clause 16, wherein said determining a set of correction weights comprises performing a Monte-Carlo simulation over said dominant asymmetry modes or model parameters corresponding to said dominant asymmetry modes.
   18. A method as in clause 17, wherein, in said simulation, the dominant asymmetry modes or model parameters corresponding thereto are floating parameters and asymmetry modes not identified as being dominant or model parameters corresponding thereto are fixed.
   19. A method as in clause 17 or 18, comprising using an alignment mark model to perform said Monte-Carlo simulation.
   20. A method as in clause 19, comprising using said alignment mark model to perform a stack simulation and determine a swing curve per determined dominant asymmetry mode, wherein each swing curve comprises a mark sensitivity metric as a function of illumination condition.
   21. A method as in clause 20, wherein each swing curve comprises a ratio of variation of aligned position as a function of illumination condition with variation of each of the dominant asymmetry modes or model parameters corresponding thereto.
   22. A method as in any of clauses 16 to 21, wherein said determining a set of correction weights comprises determining said weights such that they maximize alignment accuracy and/or minimize the mark sensitivity metric over a respective maximum range of process variations when applied to an alignment measurement.
   23. A method as in any of clauses 16 to 22, comprising applying said correction weights to an alignment measurement of a substrate performed with a plurality of illumination settings to obtain a corrected alignment measurement.
   24. A method as in clause 23, comprising performing said alignment measurement.
   25. A computer program comprising program instructions operable to perform the method of any of clauses 1 to 24, when run on a suitable apparatus.
   26. A non-transient computer program carrier comprising the computer program of clause 25.
   27. A processing system comprising a processor and a storage device comprising the computer program of clause 26.
   28. An alignment sensor operable to perform the method of any of clauses 14 to 19.
   29. A lithographic apparatus comprising:
a patterning device support for supporting a patterning device;
a substrate support for supporting a substrate; and
the alignment sensor of clause 28.
   30. A metrology device operable to perform the method of clause 24.

The breadth and scope of the present invention should not be limited by any of the above-described exemplary embodiments, but should be defined only in accordance with the following claims and their equivalents.

1. A method of identifying one or more dominant asymmetry modes relating to asymmetry in an alignment mark, the method comprising either:
steps A): obtaining alignment data relating to measurement of alignment marks on at least one substrate using a plurality of alignment conditions; identifying one or more dominant orthogonal components of the alignment data, the one or more dominant orthogonal components comprising a number of orthogonal components which together sufficiently describes variance in the alignment data; and determining an asymmetry mode as dominant if it corresponds to an expected asymmetry mode shape which best matches one of the one or more said dominant orthogonal components; or
steps B): for each known asymmetry mode: determining a sensitivity metric; and determining an asymmetry mode as dominant if the said sensitivity metric is above a sensitivity threshold.

2. The method as claimed in claim 1, comprising steps A) and wherein the number of dominant orthogonal components comprises the minimum number of orthogonal components which together sufficiently describes variance in the alignment data.

3. The method as claimed in claim 2, wherein determining the number of orthogonal components which together sufficiently describes variance in the alignment data comprises determining the number of orthogonal components required to explain a certain threshold percentage of variance.

4. The method as claimed in claim 2, wherein the alignment data comprises color-to-average data comprising a difference of each alignment value relating to a respective one of the said illumination conditions and an average alignment value over all illumination conditions.

5. The method as claimed in claim 2, wherein the determining an asymmetry mode as dominant if it corresponds to an expected asymmetry mode shape which best matches one of the one or more dominant orthogonal components comprises comparing each orthogonal component to a library of expected asymmetry mode shapes, each corresponding to at least one asymmetry mode.

6. The method as claimed in claim 5, further comprising triggering an update for the library should no good match be found for an orthogonal component within the library.

7. The method as claimed in claim 2, further comprising determining a maximum variation range for asymmetry variation for each dominant asymmetry mode.

8. The method as claimed in claim 7, wherein determining a maximum variation range comprises:
obtaining an alignment mark model for modeling performance of an alignment mark;
using the alignment mark model to determine a sensitivity metric or Jacobian of each asymmetry mode; and
determining the maximum range from the sensitivity metric or Jacobian.

9. The method as claimed in claim 1, comprising steps B) and further comprising:
obtaining an alignment mark model for modeling performance of an alignment mark; and
using the alignment mark model to determine the sensitivity metric.

10. The method as claimed in claim 9, wherein the using the alignment mark model to determine the sensitivity metric comprises using the alignment mark model to determine the Jacobian of each said asymmetry mode.

11. The method as claimed in claim 1, comprising using the dominant asymmetry mode to determine a set of correction weights to correct alignment data.

12. The method as claimed in claim 11, wherein the determining a set of correction weights comprises determining the set of weights such that they maximize alignment accuracy and/or minimize a mark sensitivity metric over a respective maximum range of process variations when applied to an alignment measurement.

13. The method as claimed in claim 11, further comprising applying the set of correction weights to an alignment measurement of a substrate performed with a plurality of illumination settings to obtain a corrected alignment measurement.

14. The method as claimed in claim 13, further comprising performing the alignment measurement.

15. (canceled)

16. A non-transitory computer program carrier comprising a computer program therein, the computer program, when executed by a computer system, configured to cause the computer system to at least either:
A) obtain alignment data relating to measurement of alignment marks on at least one substrate using a plurality of alignment conditions; identify one or more dominant orthogonal components of the alignment data, the one or more dominant orthogonal components comprising a number of orthogonal components which together sufficiently describes variance in the alignment data; and determining an asymmetry mode as dominant if it corresponds to an expected asymmetry mode shape which best matches one of the one or more dominant orthogonal components, the asymmetry mode relating to asymmetry in an alignment mark; or
B): for each known asymmetry mode relating to asymmetry in an alignment mark: determine a sensitivity metric; and determine an asymmetry mode as dominant if the sensitivity metric is above a sensitivity threshold.

17. (canceled)

18. An alignment sensor configured to perform the method of claim 1.

19. A lithographic apparatus comprising:
a patterning device support for supporting a patterning device;
a substrate support for supporting a substrate; and
the alignment sensor of claim 18.

20. A metrology device configured to perform the method of claim 1.

21. The computer program carrier of claim 16, wherein the instructions are configured to cause the computer system to perform A).

22. The computer program carrier of claim 16, wherein the instructions are configured to cause the computer system to perform B).
